(19) United States
(12) Patent Application Publication
(10) Pub. No.: US 2025/0355056 A1
(43) Pub. Date: Nov. 20, 2025

(54) BATTERY MANAGEMENT APPARATUS AND OPERATING METHOD THEREOF

(71) Applicant: LG ENERGY SOLUTION, LTD., Seoul (KR)

(72) Inventor: Jun Cheol PARK, Daejeon (KR)

(73) Assignee: LG ENERGY SOLUTION, LTD., Seoul (KR)

(21) Appl. No.: 18/866,467

(22) PCT Filed: Jun. 26, 2023
(86) PCT No.: PCT/KR2023/008868

§ 371 Date: Nov. 15, 2024

(30) Foreign Application Priority Data
Aug. 4, 2022 (KR) 10-2022-0097615

(51) Int. Cl. G01R 31/392; G01R 19/165; G01R 31/36; G01R 31/367; G01R 31/3842; G01R 31/396

(52) U.S. Cl. CPC G01R 31/392; G01R 19/16542; G01R 31/3648; G01R 31/367; G01R 31/3842; G01R 31/396

(57) ABSTRACT

A battery management apparatus according to an embodiment disclosed herein includes a measuring unit for measuring a current and a voltage of a battery and a controller for generating voltage estimation information by estimating the voltage of the battery for a second period of time after a first period of time based on first current information related to the current of the battery measured for the first period of time and first voltage information related to the voltage of the battery measured for the first period of time, determining a state of the battery based on the voltage estimation information and second voltage information related to the voltage of the battery measured for the second period of time.

### TECHNICAL FIELD

### Cross-Reference to Related Application

This application claims priority to and the benefit of Korean Patent Application No. 10-2022-0097615 filed in the Korean Intellectual Property Office on Aug. 4, 2022, the entire contents of which are incorporated herein by reference.

### TECHNICAL FIELD

Embodiments disclosed herein relate to a battery management apparatus and an operating method thereof.

### BACKGROUND ART

Recently, research and development of secondary batteries have been actively performed. Herein, the secondary batteries, which are chargeable/dischargeable batteries, may include all of conventional nickel (Ni)/cadmium (Cd) batteries, Ni/metal hydride (MH) batteries, etc., and recent lithium-ion batteries. Among the secondary batteries, a lithium-ion battery has a much higher energy density than those of the conventional Ni/Cd batteries, Ni/MH batteries, etc. Moreover, the lithium-ion battery may be manufactured to be small and lightweight, such that the lithium-ion battery has been used as a power source of mobile devices, and recently, a use range thereof has been extended to power sources for electric vehicles, attracting attention as next-generation energy storage media.

An energy storage system (ESS) battery needs a technique for detecting a defect of a battery because occurrence of the defect may result in a huge accident such as fire, etc. The technique for detecting a defect of a battery has been variously developed, but most methods perform simple comparison such as voltage, current, or temperature deviations of battery cells or voltage drops of a specific battery cell, requiring a method for accurately detecting a defect of a battery. That is, a technique for detecting a battery cell having an abnormal behavior according to a state of a battery is required.

### DISCLOSURE

### Technical Problem

Embodiments disclosed herein aim to provide a battery management apparatus and an operating method thereof in which an unusual abnormal behavior undetectable based on a deviation between battery cells may be detected.

Embodiments disclosed herein aim to provide a battery management apparatus and an operating method thereof in which abnormality of a battery may be detected by estimating future voltage information based on voltage information and current information for a specific period of time.

Technical problems of the embodiments disclosed herein are not limited to the above-described technical problems, and other unmentioned technical problems would be clearly understood by one of ordinary skill in the art from the following description.

### Technical Solution

A battery management apparatus according to an embodiment disclosed herein includes a measuring unit configured to measure a current and a voltage of a battery and a controller configured to generate voltage estimation information by estimating the voltage of the battery for a second period of time after a first period of time based on first current information related to the current of the battery measured for the first period of time and first voltage information related to the voltage of the battery measured for the first period of time, determine a state of the battery based on the voltage estimation information and second voltage information related to the voltage of the battery measured for the second period of time.

In an embodiment, the controller may be further configured to determine that an abnormality occurs in the battery when a difference between the voltage estimation information and the second voltage information is greater than or equal to a threshold value.

In an embodiment, the controller may be further configured to generate the voltage estimation information based on second current information related to the current of the battery measured for the second period of time and initial voltage information of the battery measured for the second period of time.

In an embodiment, the controller may be further configured to learn the first current information and the first voltage information through a long short-term memory (LSTM) algorithm.

In an embodiment, the controller may be further configured to generate the voltage estimation information based on the LSTM algorithm, the LSTM algorithm is trained.

In an embodiment, the controller may be further configured to update the LSTM algorithm based on the second voltage information and second current information related to the current of the battery measured for the second period of time.

In an embodiment, the battery management apparatus may further include a storing unit, in which the storing unit is further configured to store the LSTM algorithm trained every first period of time.

In an embodiment, the controller may be further configured to generate voltage estimation information of a replacement battery for the second period of time based on the stored LSTM algorithm when there is the replacement battery.

In an embodiment, the controller may be further configured to generate the voltage estimation information when the battery has a state of health (SoH) in a specific range.

In an embodiment, the controller may be further configured to change an algorithm for generating the voltage estimation information when the SoH of the battery falls out of the specific range.

In an embodiment, the controller may be further configured to update the algorithm for generating the voltage estimation information for every first period of time.

In an embodiment, the controller may be further configured to train an algorithm related to a relationship between the first current information and the first voltage information and generate the voltage estimation information based on the trained algorithm.

An operating method of a battery management apparatus according to an embodiment disclosed herein includes measuring a current and a voltage of a battery, generating voltage estimation information by estimating the voltage of the battery for a second period of time after a first period of time based on first current information related to the current of the battery measured for the first period of time and first voltage information related to the voltage of the battery measured for the first period of time, determining a state of the battery based on the voltage estimation information and second voltage information related to the voltage of the battery measured for the second period of time.

In an embodiment, the determine of the state of the battery based on the voltage estimation information and the second voltage information related to the voltage of the battery measured for the second period of time may include determining that an abnormality occurs in the battery when a difference between the voltage estimation information and the second voltage information is greater than or equal to a threshold value.

In an embodiment, the generating of the voltage estimation information by estimating the voltage of the battery for the second period of time after the first period of time based on the first current information related to the current of the battery measured for the first period of time and the first voltage information related to the voltage of the battery measured for the first period of time may include learning the first current information and the first voltage information through an algorithm and generating the voltage estimation information based on the trained algorithm.

In an embodiment, the operating method may further include updating the algorithm based on the second voltage information and second current information related to the current of the battery measured for the second period of time.

In an embodiment, the operating method may further include storing an algorithm for every first period of time.

In an embodiment, the operating method may further include generating voltage estimation information of a replacement battery for the second period of time based on the stored algorithm when the battery is replaced.

### Advantageous Effects

The battery management apparatus and the operating method thereof according to an embodiment disclosed herein may detect a special abnormal behavior undetectable through simple comparison in voltage or current between battery cells.

The battery management apparatus and the operating method thereof according to an embodiment disclosed herein may determine a state of the battery by estimating voltage information for the second period of time based on the first current information and the voltage information and comparing the estimated voltage information with the measured voltage information.

The battery management apparatus and the operating method thereof according to an embodiment disclosed herein may determine the state of the battery by training an algorithm related to a relationship between the current information of the battery and the voltage information of the battery for a specific period of time.

The battery management apparatus and the operating method thereof according to an embodiment disclosed herein may determine the state of the battery by storing the trained algorithm and estimating voltage information through an appropriate algorithm for the replaced battery even when the battery is replaced.

The battery management apparatus and the operating method thereof according to an embodiment disclosed herein may estimate voltage information by using the same algorithm for batteries having similar SoH and train a new algorithm to estimate voltage information of the battery when the SoH change over time.

Moreover, various effects recognized directly or indirectly from the disclosure may be provided.

### DESCRIPTION OF DRAWINGS

FIG. 1 is a block diagram of a general battery pack.

FIG. 2 is a block diagram of a battery management apparatus according to an embodiment disclosed herein.

FIG. 3 is a view showing an example of determining a state of a battery by a battery management apparatus, according to an embodiment disclosed herein.

FIG. 4 shows an example in which a battery management apparatus stores an algorithm, according to an embodiment disclosed herein.

FIG. 5 is a flowchart of an operating method of a battery management apparatus according to an embodiment disclosed herein.

FIGS. 6 to 7 are flowcharts showing in detail an operating method of a battery management apparatus, according to an embodiment disclosed herein.

FIG. 8 is a block diagram showing a hardware configuration of a computing system for performing an operating method of a battery management apparatus, according to an embodiment disclosed herein.

### MODE FOR INVENTION

Hereinafter, embodiments disclosed in this document will be described in detail with reference to the exemplary drawings. In adding reference numerals to components of each drawing, it should be noted that the same components are given the same reference numerals even though they are indicated in different drawings. In addition, in describing the embodiments disclosed in this document, when it is determined that a detailed description of a related known configuration or function interferes with the understanding of an embodiment disclosed in this document, the detailed description thereof will be omitted.

To describe a component of an embodiment disclosed herein, terms such as first, second, A, B, (a), (b), etc., may be used. These terms are used merely for distinguishing one component from another component and do not limit the component to the essence, sequence, order, etc., of the component. The terms used herein, including technical and scientific terms, have the same meanings as terms that are generally understood by those skilled in the art, as long as the terms are not differently defined. Generally, the terms defined in a generally used dictionary should be interpreted as having the same meanings as the contextual meanings of the relevant technology and should not be interpreted as having ideal or exaggerated meanings unless they are clearly defined in the present application.

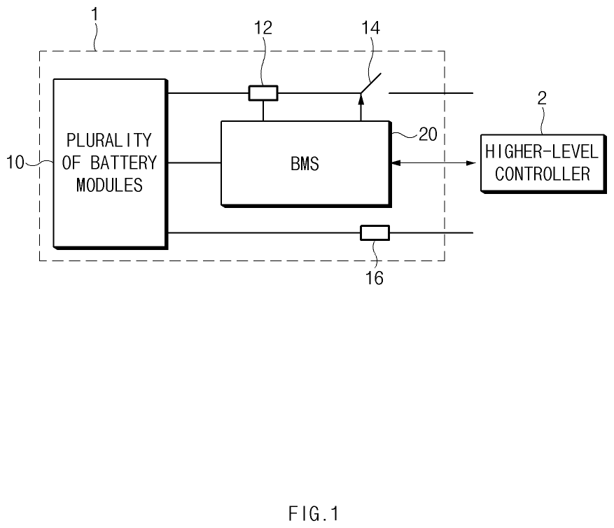

FIG. 1 is a block diagram of a general battery pack.

Referring to FIG. 1, a battery control system including a battery pack 1 and a higher-level controller 2 included in a higher-level system according to an embodiment of the present disclosure is schematically shown.

As shown in FIG. 1, the battery pack 1 may include one or more battery modules 10 each including one or more battery cells and chargeable/dischargeable, a switching unit 14 serially connected to a positive (+) terminal side or a negative (−) terminal side of the battery module 10 to control a charging/discharging current flow of the battery module 10, and a battery management system 20 for control and management to prevent over-charging and over-discharging by monitoring voltage, current, temperature, etc., of the battery pack 1. The battery pack 1 may include the battery module 10, the sensor 12, 16, the switching unit 14, and the battery management system 20 provided in plural.

Herein, as the switching unit 14 which is an element for controlling a current flow for charging or discharging of the plurality of battery modules 10, for example, at least one relay, magnetic contactor, etc., may be used according to specifications of the battery pack 1.

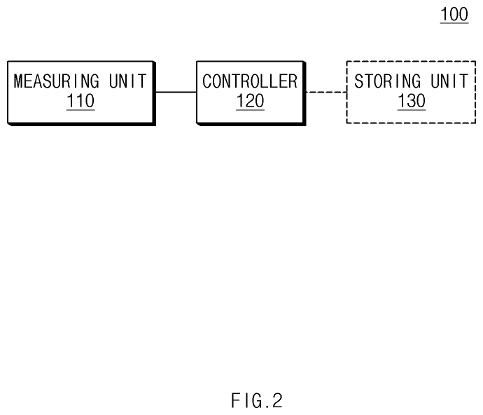

The battery management system 20, which is an interface for receiving measurement values of the above-described various parameter values, may include a plurality of terminals and a circuit, etc., connected thereto to process input values. The battery management system 20 may control on/off of the switching unit 14, e.g., a relay, a contactor, etc., and may be connected to the battery module 10 to monitor the state of each battery module 10. According to an embodiment, the battery management system 20 may include a battery management apparatus 100 of FIG. 2. According to another embodiment, the battery management system 20 may be different from the battery management apparatus 100 of FIG. 2. That is, the battery management apparatus 100 of FIG. 2 may be included in the battery pack 1 and may be configured as another device outside the battery pack 1.

The higher-level controller 2 may transmit a control signal regarding the battery module 10 to the battery management system 20. Thus, the battery management system 20 may also be controlled in terms of an operation thereof based on a signal applied from the higher-level controller 2.

FIG. 2 is a block diagram of a battery management apparatus according to an embodiment disclosed herein.

Referring to FIG. 2, the battery management apparatus 100 according to an embodiment disclosed herein may include a measuring unit 110 and a controller 120. Depending on an embodiment, the battery management apparatus 100 may be included in the battery management system 20 of FIG. 1 or may be another device that is different from the battery management system 20 of FIG. 1. According to an embodiment, the battery management apparatus 100 may optionally include a storing unit 130.

The measuring unit 110 may measure a current and a voltage of a battery. For example, the measuring unit 110 may measure first current information related to a current of a battery, measured for a first period of time, and first voltage information related to a voltage of the battery, measured for the first period of time. In another example, the measuring unit 110 may include a current sensor and a voltage sensor and measure the first current information and the first voltage information through the current sensor and the voltage sensor. In another example, the measuring unit 110 may measure current information and voltage information of each of a battery pack, a battery module, or a battery cell included in the battery. According to an embodiment, the first period of time may be one month, without being limited thereto. According to another embodiment, the first period of time may be a period of time for which a state of health (SoH) of the battery does not change.

According to an embodiment, the measuring unit 110 may measure the first current information and the first voltage information for every first period of time. For example, when the first period of time is one month, the measuring unit 110 may measure the current information of the battery and the voltage information of the battery for the first one month, and measure the current information of the battery and the voltage information of the battery again for the next one month. That is, the measuring unit 110 may repeatedly measure the first current information and the first voltage information.

The measuring unit 110 may measure second current information related to a current of the battery for a second period of time after the first period of time, and second voltage information related to a voltage of the battery for the second period of time. For example, the second period of time may be one day, without being limited thereto. In another example, the second period of time may be a period of time for which the controller 120 estimates voltage information of the battery.

According to an embodiment, the measuring unit 110 may measure the second current information and the second voltage information for every second period of time. For example, when the second period of time is one day, the measuring unit 110 may measure the second current information and the second voltage information for the first one day, and measure the second current information and the second voltage information again for the next day. That is, the measuring unit 110 may repeatedly measure the second current information and the second voltage information.

The controller 120 may estimate a voltage of the battery for the second period of time after the first period of time based on the first current information and the first voltage information to generate voltage estimation information.

The controller 120 may determine a state of the battery based on the estimated voltage estimation information and the second voltage information related to the voltage of the battery measured for the second period of time. For example, the controller 120 may compare the generated voltage estimation information with the second voltage information and determine that abnormality occurs in the battery when a difference between the voltage estimation information and the second voltage information is greater than or equal to a threshold value. According to an embodiment, the controller 120 may determine that abnormality occurs in the battery based on at least any one of an average of differences between voltage estimation information and second voltage information, an accumulated difference for the second period of time, an absolute value of the difference, and a root mean square of the differences, without being limited to the foregoing method.

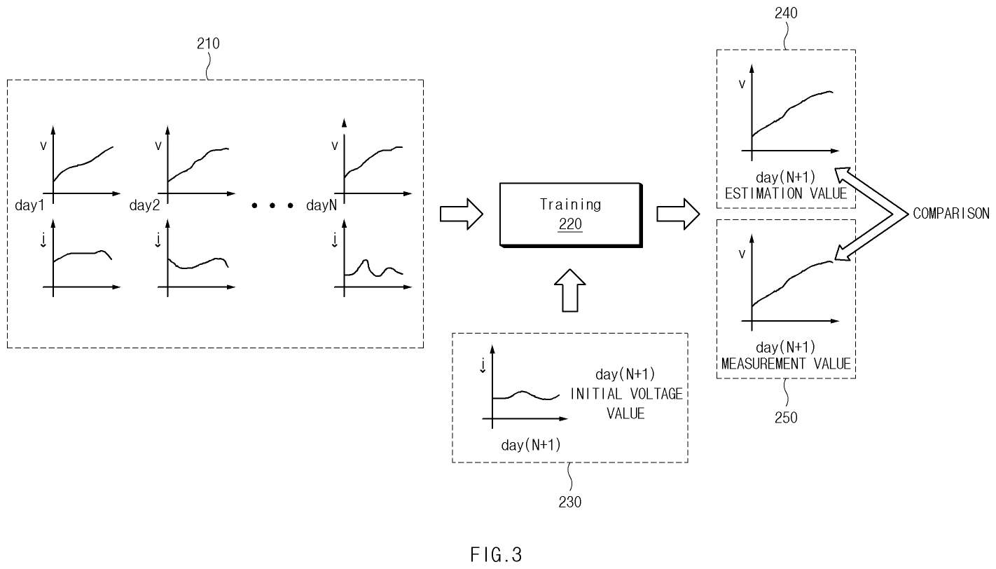

FIG. 3 is a view showing an example of determining a state of a battery by a battery management apparatus, according to an embodiment disclosed herein. According to an embodiment, an example shown in FIG. 3 may be performed by the battery management apparatus 100 of FIG. 2.

Referring to FIG. 3, the measuring unit 110 may include first current information and first voltage information 210. For example, a first period of time may be from day 1 to day N, and the measuring unit 110 may measure a current of a battery from day 1 to day N and a voltage of the battery from day 1 to day N. The first current information and first voltage information 210 may be put through by training 220 an algorithm related to a relationship between the current information of the battery and the voltage information of the battery for a specific period of time.

The measuring unit 110 may also measure second current information and initial voltage information 230 of a second period of time and measure second voltage information 250. For example, the second period of time may be day N+1, and the measuring unit 110 may measure current information of day N+1 and voltage information of day N+1.

The controller 120 may also generate voltage estimation information 240 based on the second current information and the initial voltage information 230 of the second period of time. For example, the controller 120 may estimate voltage information of day N+1 based on the current information of day N+1 and the initial voltage information of day N+1.

According to an embodiment, the controller 120 may learn the first current information and the first voltage information 210 through a long short-term memory (LSTM) algorithm as indicated by 220. For example, the controller 120 may train an algorithm related to a relationship between the first current information and the first voltage information 210 as indicated by 220.

The controller 120 may generate the voltage estimation information 240 based on the trained algorithm. For example, the controller 120 may input the current information of day N+1 and the initial voltage information 230 of day N+1 to the trained algorithm, and generate and output the voltage information 240 of day N+1 estimated based on the algorithm.

According to an embodiment, the controller 120 may update an algorithm based on the second current information and the second voltage information. For example, the controller 120 may train an algorithm related to a relationship between voltage information of a battery and current information of the battery, further based on the second current information and the second voltage information in addition to the first current information and the first voltage information.

According to an embodiment, the controller 120 may update the algorithm based on the current information of the battery measured for every second period of time and the voltage information of the battery measured for every second period of time. For example, the controller 120 may train and update the algorithm based on current information of day 1 to day N+1 and the voltage information of day 1 to day N+1. In another example, the controller 120 may update the algorithm based on the current information of the battery of day N+1 and the voltage information of the battery of day N+1. According to an embodiment, the controller 120 may estimate voltage information of the battery of day N+2 based on the updated algorithm to generate voltage estimation information of the battery of day N+2.

The controller 120 may determine a state of the battery based on the generated voltage estimation information 240 and the second voltage information 250. For example, the controller 120 may determine the state of the battery by comparing the voltage estimation information 240 with the second voltage information 250. In another example, the controller 120 may determine that abnormality occurs in the battery when a difference between the voltage estimation information 240 and the second voltage information 250 is greater than or equal to a threshold value.

Referring back to FIG. 2, the controller 120 may generate voltage estimation information regarding the battery having a SoH in a specific range. For example, when the SoH falls out of the specific range, the relationship between the current information of the battery and the voltage information of the battery may change, such that the controller 120 may generate voltage estimation information through the same algorithm for a battery having a SoH in the specific range.

According to an embodiment, when the SoH of the battery falls out of the specific range, the controller 120 may change the algorithm for generating voltage estimation information. For example, the controller 120 may change the algorithm for every first period of time.

According to an embodiment, the battery management apparatus 100 may further include the storing unit 130. The storing unit 130 may store the algorithm trained for every first period of time.

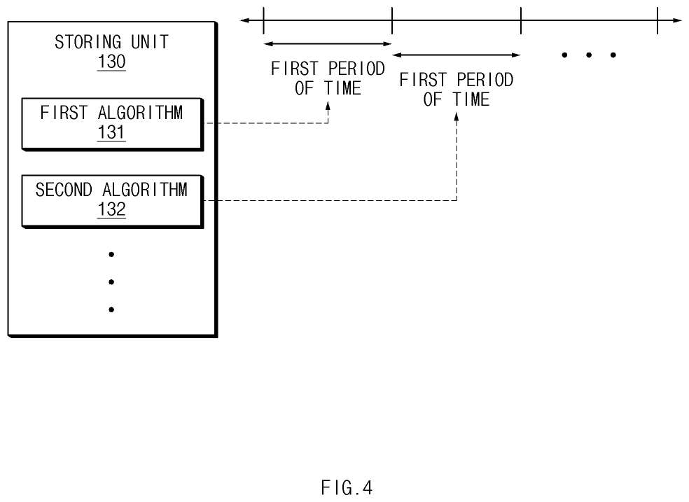

FIG. 4 shows an example in which a battery management apparatus stores an algorithm, according to an embodiment disclosed herein.

Referring to FIG. 4, the storing unit 130 according to an embodiment disclosed herein may store the algorithm trained for every first period of time. Thus, the storing unit 130 may store a plurality of algorithms 131 and 132.

According to an embodiment, a first algorithm 131 stored in the storing unit 130 may be an algorithm trained by the controller 120 for the initial first period of time. In addition, a second algorithm 132 stored in the storing unit 130 may be an algorithm trained by the controller 120 during the second first period of time. That is, the controller 120 may train an algorithm related to a relationship between the current information of the battery and the voltage information of the battery for every first period of time and store the trained algorithm in the storing unit 130.

According to an embodiment, the controller 120 may generate voltage estimation information for every second period of time after the initial first period of time based on the first algorithm 131. The controller 120 may train the second algorithm 132 based on the second first current information and the second first voltage information by accumulating the current information of the battery measured for every second period of time and the voltage information of the battery measured for every second period of time. In this case, the controller 120 may generate voltage estimation information for every second period of time after the second first period of time based on the second algorithm 132.

According to an embodiment, the controller 120 may generate the voltage estimation information based on an algorithm corresponding to each battery. For example, the controller 120 may generate voltage estimation information of a replaced battery for the second period of time based on the algorithm stored in the storing unit 130 when there is the replaced battery. When the battery is replaced, a SoH indicating a level of deterioration may be different from those of batteries not replaced, such that the controller 120 may generate voltage estimation information of the replaced battery based on an algorithm corresponding to a period for which the replaced battery is included.

The battery management apparatus 100 according to an embodiment disclosed herein may detect a special abnormal behavior undetectable through simple comparison in voltage or current between battery cells.

The battery management apparatus 100 according to an embodiment disclosed herein may determine a state of the battery by estimating voltage information for the second period of time based on the first current information and the voltage information and comparing the estimated voltage information with the measured voltage information.

The battery management apparatus 100 according to an embodiment disclosed herein may determine the state of the battery by training an algorithm related to a relationship between the current information of the battery and the voltage information of the battery for a specific period of time.

The battery management apparatus 100 according to an embodiment disclosed herein may determine the state of the battery by storing the trained algorithm and estimating voltage information through an appropriate algorithm for the replaced battery even when the battery is replaced.

The battery management apparatus 100 according to an embodiment disclosed herein may estimate voltage information by using the same algorithm for batteries having similar SoH and train a new algorithm to estimate voltage information of the battery when the SoH change over time.

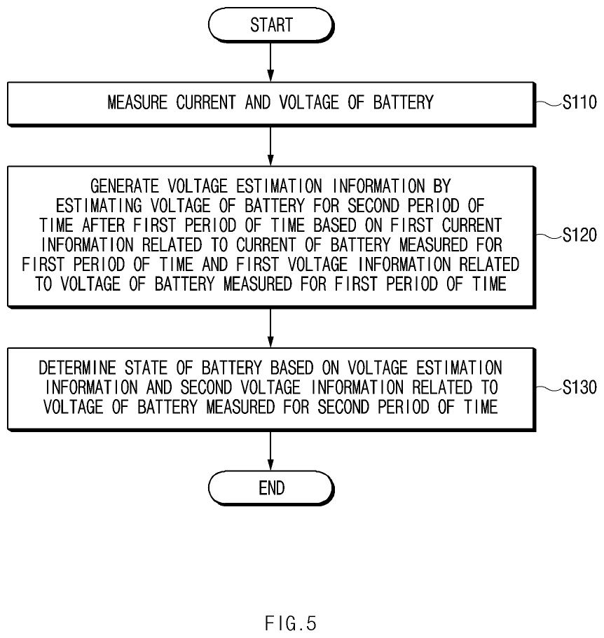

FIG. 5 is a flowchart of an operating method of a battery management apparatus according to an embodiment disclosed herein.

According to an embodiment, operations shown in FIG. 5 may be performed by the battery management apparatus 100 of FIG. 2.

Referring to FIG. 5, an operating method of the battery management apparatus 100 according to an embodiment disclosed herein may include operation S110 of measuring a current and a voltage of a battery, operation S120 of generating voltage estimation information by estimating the voltage of the battery for a second period of time after a first period of time based on first current information related to a current of the battery measured for a first period of time and first voltage information related to a voltage of the battery measured for the first period of time, and operation S130 of determining a state of the battery based on the voltage estimation information and second voltage information related to a voltage of the battery measured for the second period of time.

In operation S110, the measuring unit 110 may measure a current and a voltage of a battery. For example, the measuring unit 110 may measure first current information related to a current of a battery, measured for a first period of time, and first voltage information related to a voltage of the battery, measured for the first period of time. In another example, the measuring unit 110 may include a current sensor and a voltage sensor and measure the first current information and the first voltage information through the current sensor and the voltage sensor. In another example, the measuring unit 110 may measure current information and voltage information of each of a battery pack, a battery module, or a battery cell included in the battery. According to an embodiment, the first period of time may be one month, without being limited thereto. According to another embodiment, the first period of time may be a period of time for which a state of health (SoH) of the battery does not change.

According to an embodiment, in operation S100, the measuring unit 110 may measure the first current information and the first voltage information for every first period of time. For example, when the first period of time is one month, the measuring unit 110 may measure the current information of the battery and the voltage information of the battery for the first one month, and measure the current information of the battery and the voltage information of the battery again for the next one month. That is, the measuring unit 110 may repeatedly measure the first current information and the first voltage information.

In operation S110, the measuring unit 110 may measure second current information related to a current of the battery for a second period of time after the first period of time, and second voltage information related to a voltage of the battery for the second period of time. For example, the second period of time may be one day, without being limited thereto. In another example, the second period of time may be a period of time for which the controller 120 estimates voltage information of the battery.

According to an embodiment, in operation S110, the measuring unit 110 may measure the second current information and the second voltage information for every second period of time. For example, when the second period of time is one day, the measuring unit 110 may measure the second current information and the second voltage information for the first one day, and measure the second current information and the second voltage information again for the next day. That is, the measuring unit 110 may repeatedly measure the second current information and the second voltage information.

In operation S120, the measuring unit 120 may generate the voltage estimation information based on the first current information related to the current of the battery, measured for the first period of time, and the first voltage information related to the voltage of the battery, measured for the first period of time. For example, the controller 120 may train the algorithm related to the relationship between the first current information and the first voltage information and generate voltage estimation information based on the trained algorithm, second current information related to the current of the battery, measured for the second period of time, and the initial voltage information of the second period of time.

In operation S130, the controller 120 may determine the state of the battery based on the voltage estimation information and the second voltage information. For example, the controller 120 may determine that abnormality occurs in the battery when a difference between the voltage estimation information and the second voltage information related to the voltage of the battery measured for the second period of time is greater than or equal to the threshold value.

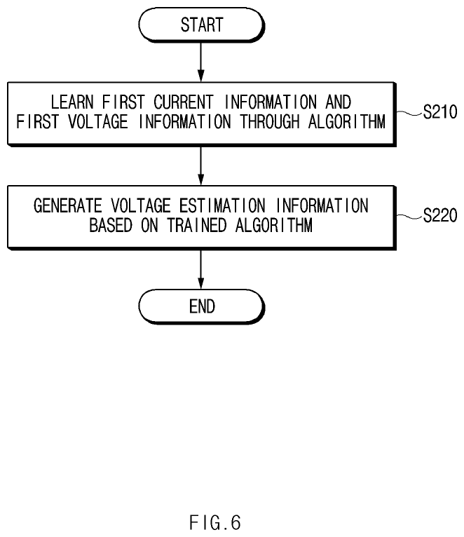

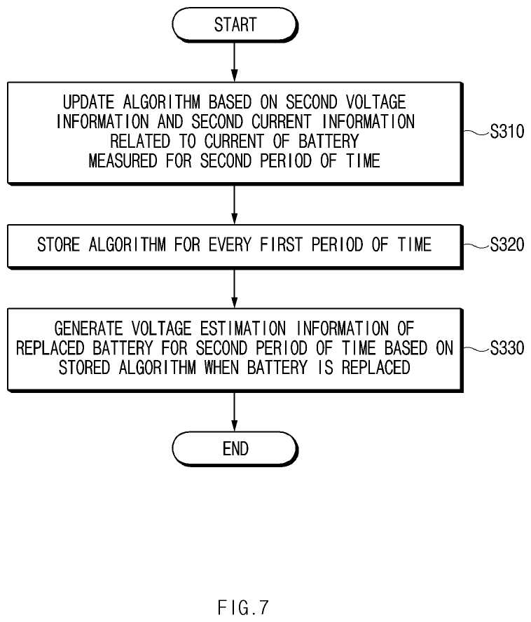

FIGS. 6 to 7 are flowcharts showing in detail an operating method of a battery management apparatus, according to an embodiment disclosed herein. According to an embodiment, operations shown in FIGS. 6 and 7 may be performed by the battery management apparatus 100 of FIG. 2.

Referring to FIG. 6, an operating method of the battery control apparatus 100 according to an embodiment disclosed herein may include operation S210 of learning first current information and first voltage information through an algorithm and operation S220 of generating voltage estimation information based on the trained algorithm. According to an embodiment, operations S210 and S220 may be included in operation S120 of FIG. 5.

That is, in operation S210, the controller 120 may learn the first current information and the first voltage information through the algorithm. For example, the controller 120 may learn the first current information and the first voltage information through an LSTM algorithm. In another example, the controller 120 may train an algorithm related to a relationship between the first current information and the first voltage information.

In operation S220, the controller 120 may generate the voltage estimation information based on the trained algorithm.

Referring to FIG. 7, the operating method of the battery management apparatus 100 according to an embodiment disclosed herein may include operation S310 of updating an algorithm based on the second voltage information and the second current information related to the current of the battery measured for the second period of time and operation S330 of predicting voltage information of the replaced battery for the second period of time based on the stored algorithm when the battery is replaced.

In operation S310, the controller 120 may update the algorithm based on the second voltage information and the second current information related to the current of the battery measured for the second period of time. For example, the controller 120 may train an algorithm related to a relationship between voltage information and current information, further based on the second current information and the second voltage information in addition to the first current information and the first voltage information. According to an embodiment, the controller 120 may update the algorithm based on the current information of the battery measured for every second period of time and the voltage information of the battery measured for every second period of time.

In operation S320, the storing unit 130 may store the algorithm for every first period of time. For example, the storing unit 130 may store a plurality of algorithms by storing the algorithm for every first period of time.

In operation S330, the controller 120 may generate the voltage estimation information of the replaced battery for the second period of time based on the stored algorithm when the battery is replaced. For example, the controller 120 may generate voltage estimation information of a replaced battery for the second period of time based on the algorithm stored in the storing unit 130 when there is the replaced battery. When the battery is replaced, a SoH indicating a level of deterioration may be different from those of batteries not replaced, such that the controller 120 may generate voltage estimation information of the replaced battery based on an algorithm corresponding to a period for which the replaced battery is included.

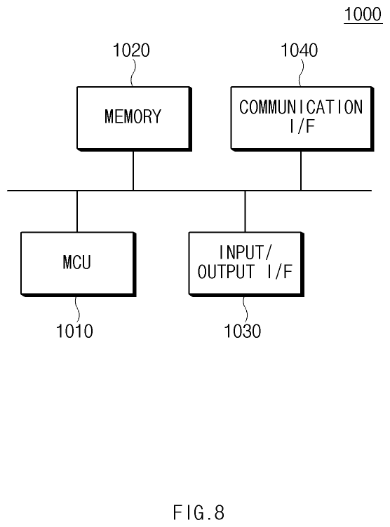

FIG. 8 is a block diagram showing a hardware configuration of a computing system for performing an operating method of a battery management apparatus, according to an embodiment disclosed herein.

Referring to FIG. 8, a computing system 1000 according to an embodiment disclosed herein may include an MCU 1010, a memory 1020, an input/output I/F 1030, and a communication I/F 1040.

The MCU 1010 may be a processor that executes various programs (e.g., a program for collecting battery voltage information or current information, a program for training an algorithm related to a relationship between the battery voltage information and the battery current information, a program for estimating the battery voltage information, a program for determining whether the battery is replaced, a program for determining a state of the battery, etc.) stored in the memory 1020, processes various information including the battery voltage information, the battery current information, the algorithm for estimating the battery voltage information, the battery state information, etc., through these programs, and executes the above-described functions of the controller included in the battery management apparatus shown in FIG. 2.

The memory 1020 may store various programs such as the program for collecting the battery voltage information or current information, the program for training the algorithm related to the relationship between the battery voltage information and the battery current information, the program for estimating the battery voltage information, the program for determining whether the battery is replaced, the program for determining the state of the battery, etc. The memory 1020 may store various information such as the voltage information of the battery, the current information of the battery, the algorithm for estimating the battery voltage information, the battery state information, etc. According to an embodiment, the memory 1020 may be substantially the same as the storing unit 130 of FIG. 2.

The memory 1020 may be provided in plural, depending on a need. The memory 1020 may be volatile memory or non-volatile memory. For the memory 1020 as the volatile memory, random access memory (RAM), dynamic RAM (DRAM), static RAM (SRAM), etc., may be used. For the memory 1020 as the nonvolatile memory, read only memory (ROM), programmable ROM (PROM), electrically alterable ROM (EAROM), erasable PROM (EPROM), electrically erasable PROM (EEPROM), flash memory, etc., may be used. The above-listed examples of the memory 1020 are merely examples and are not limited thereto.

The input/output I/F 1030 may provide an interface for transmitting and receiving data by connecting an input device (not shown) such as a keyboard, a mouse, a touch panel, etc., and an output device such as a display (not shown), etc., to the MCU 1010.

The communication I/F 1040, which is a component capable of transmitting and receiving various data to and from a server, may be various devices capable of supporting wired or wireless communication. For example, the battery management apparatus may transmit and receive information such as the voltage information of the battery, the current information of the battery, the algorithm for estimating the battery voltage information, the battery state information from an external server separately provided through the communication I/F 1040.

As such, a computer program according to an embodiment disclosed herein may be recorded in the memory 1020 and processed by the MCU 1010, thus being implemented as a module that performs functions shown in FIG. 2.

The above description is merely illustrative of the technical idea of the present disclosure, and various modifications and variations will be possible without departing from the essential characteristics of embodiments of the present disclosure by those of ordinary skill in the art to which the embodiments disclosed herein pertains.

Therefore, the embodiments disclosed herein are intended for description rather than limitation of the technical spirit of the embodiments disclosed herein and the scope of the technical spirit of the present disclosure is not limited by these embodiments disclosed herein. The protection scope of the technical spirit disclosed herein should be interpreted by the following claims, and all technical spirits within the same range should be understood to be included in the range of the present disclosure.

1. A battery management apparatus comprising:
a measuring unit configured to measure a current and a voltage of a battery; and
a controller configured to:
generate voltage estimation information by estimating the voltage of the battery for a second period of time after a first period of time based on first current information related to the current of the battery measured for the first period of time and first voltage information related to the voltage of the battery measured for the first period of time,
determine a state of the battery based on the voltage estimation information and second voltage information related to the voltage of the battery measured for the second period of time.

2. The battery management apparatus of claim 1, wherein the controller is further configured to determine that an abnormality occurs in the battery when a difference between the voltage estimation information and the second voltage information is greater than or equal to a threshold value.

3. The battery management apparatus of claim 1, wherein the controller is further configured to generate the voltage estimation information based on second current information related to the current of the battery measured for the second period of time and initial voltage information of the battery measured for the second period of time.

4. The battery management apparatus of claim 1, wherein the controller is further configured to learn the first current information and the first voltage information through a long short-term memory (LSTM) algorithm.

5. The battery management apparatus of claim 4, wherein the controller is further configured to generate the voltage estimation information based on the LSTM algorithm, and
wherein the LSTM algorithm is trained.

6. The battery management apparatus of claim 4, wherein the controller is further configured to update the LSTM algorithm based on the second voltage information and second current information related to the current of the battery measured for the second period of time.

7. The battery management apparatus of claim 4, further comprising a storing unit, wherein the storing unit is further configured to store the LSTM algorithm trained every first period of time.

8. The battery management apparatus of claim 7, wherein the controller is further configured to generate voltage estimation information of a replacement battery for the second period of time based on the stored LSTM algorithm when there is the replacement battery.

9. The battery management apparatus of claim 1, wherein the controller is further configured to generate the voltage estimation information when the battery has a state of health (SoH) in a specific range.

10. The battery management apparatus of claim 9, wherein the controller is further configured to change an algorithm for generating the voltage estimation information when the SoH of the battery falls out of the specific range.

11. The battery management apparatus of claim 10, wherein the controller is further configured to update the algorithm for generating the voltage estimation information for every first period of time.

12. The battery management apparatus of claim 1, wherein the controller is further configured to:
train an algorithm related to a relationship between the first current information and the first voltage information; and
generate the voltage estimation information based on the trained algorithm.

13. An operating method of a battery management apparatus, the operating method comprising:
measuring a current and a voltage of a battery;
generating voltage estimation information by estimating the voltage of the battery for a second period of time after a first period of time based on first current information related to the current of the battery measured for the first period of time and first voltage information related to the voltage of the battery measured for the first period of time; and
determining a state of the battery based on the voltage estimation information and second voltage information related to the voltage of the battery measured for the second period of time.

14. The operating method of claim 13, wherein the determine of the state of the battery based on the voltage estimation information and the second voltage information related to the voltage of the battery measured for the second period of time comprises determining that an abnormality occurs in the battery when a difference between the voltage estimation information and the second voltage information is greater than or equal to a threshold value.

15. The operating method of claim 13, wherein the generating of the voltage estimation information by estimating the voltage of the battery for the second period of time after the first period of time based on the first current information related to the current of the battery measured for the first period of time and the first voltage information related to the voltage of the battery measured for the first period of time comprises:
learning the first current information and the first voltage information through an algorithm; and
generating the voltage estimation information based on the trained algorithm.

16. The operating method of claim 15, further comprising updating an algorithm based on the second voltage information and second current information related to the current of the battery measured for the second period of time.

17. The operating method of claim 15, further comprising storing an algorithm that is trained every first period of time.

18. The operating method of claim 17, further comprising generating voltage estimation information of a replacement battery for the second period of time based on the stored algorithm when the battery is replaced.
